(19) United States
(12) Patent Application Publication
(10) Pub. No.: US 2026/0178313 A1
(43) Pub. Date: Jun. 25, 2026

(54) CONTROL DEVICE OF VEHICLE AND STORAGE MEDIUM

(71) Applicant: TOYOTA JIDOSHA KABUSHIKI KAISHA, Toyota-shi (JP)

(72) Inventors: Kazuki FUKAZAWA, Toyota-shi (JP); Kento Ooe, Toyota-shi (JP)

(73) Assignee: TOYOTA JIDOSHA KABUSHIKI KAISHA, Toyota-shi (JP)

(21) Appl. No.: 19/397,989

(22) Filed: Nov. 23, 2025

(30) Foreign Application Priority Data
Dec. 23, 2024 (JP) 2024-226267

(51) Int. Cl. G06F 8/65; G11C 16/10

(52) U.S. Cl. CPC G06F 8/65; G11C 16/105

(57) ABSTRACT

A control device of a vehicle includes a storage unit configured to store individual vehicle information of a vehicle and a setting value related to the vehicle, and a controller configured to reject storage of a new setting value in the storage unit even when the new setting value is written in the setting value by a service tool, in a case where a determination is made that the vehicle satisfies a predetermined condition related to regulations, based on the individual vehicle information, and to store the new setting value in the storage unit when the new setting value is written in the setting value by the service tool, in a case where a determination is made that the vehicle does not satisfy the predetermined condition, based on the individual vehicle information.

### CROSS-REFERENCE TO RELATED APPLICATION

This application claims priority to Japanese Patent Application No. 2024-226267 filed on December 23, 2024. The disclosure of the above-identified application, including the specification, drawings, and claims, is incorporated by reference herein in its entirety.

### BACKGROUND

### 1. Technical Field

The present disclosure relates to a control device of a vehicle and a storage medium.

### 2. Description of Related Art

For example, Japanese Unexamined Patent Application Publication No. 2014-091349 (JP 2014-091349 A) discloses a device that performs automatic brake control for reducing a collision damage between a host vehicle and an obstacle based on a detection result of a clearance sonar sensor (hereinafter, a sonar sensor) provided in a bumper of the host vehicle.

### SUMMARY

In the market, there is a need to retrofit an exterior part, such as a bull bar and a nudge bar, to a bumper. In general, various types of control, such as automatic brake control and warning control using a detection result of a sonar sensor, are performed based on information (hereinafter, also referred to as sensor information) regarding an installation position of the sonar sensor, and the like. The sensor information is stored in an in-vehicle electronic control unit (ECU) at the time of manufacturing a vehicle. Therefore, in a case where the exterior part is retrofit to the bumper, in order to reduce erroneous operations in the various types of control, the sensor information stored in the ECU needs to be rewritten at a dealer, a repair shop, or the like.

However, depending on a destination where the vehicle is actually used, such rewriting may be restricted by regulations. In addition, when systems corresponding to destinations are developed and manufactured in order to individually address jurisdictions, there is a problem that a large amount of time and effort is required for operation, resulting in an increase in cost.

An object of a technology of the present disclosure is to appropriately process writing of information stored in an in-vehicle storage unit in consideration of a jurisdiction.

A technology of the present disclosure is a control device of a vehicle. The control device includes: a storage unit configured to store individual vehicle information of the vehicle and a setting value relating to the vehicle; and a controller configured to reject, in a case where a determination is made based on the individual vehicle information that the vehicle satisfies a predetermined condition relating to a regulation, storing a new setting value as the setting value in the storage unit even when the new setting value is written by a service tool, and store, in a case where a determination is made based on the individual vehicle information that the vehicle does not satisfy the predetermined condition, the new setting value in the storage unit when the new setting value is written by the service tool.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic diagram showing a hardware configuration of a vehicle to which a control device according to the present embodiment is applied;

FIG. 2 is a schematic diagram illustrating an example of the installation of the sonar sensor;

FIG. 3 is a schematic diagram showing a software configuration of the control device according to the present embodiment;

FIG. 4 is a flowchart illustrating a flow of the writing process according to the first embodiment;

FIG. 5 is a flowchart illustrating a flow of the writing process according to the second embodiment; and

FIG. 6 is a flowchart illustrating a flow of the writing process according to the third embodiment.

### DETAILED DESCRIPTION OF EMBODIMENTS

Hereinafter, a control device of a vehicle and a program according to the present embodiment will be described with reference to the drawings.

### Entire Configuration

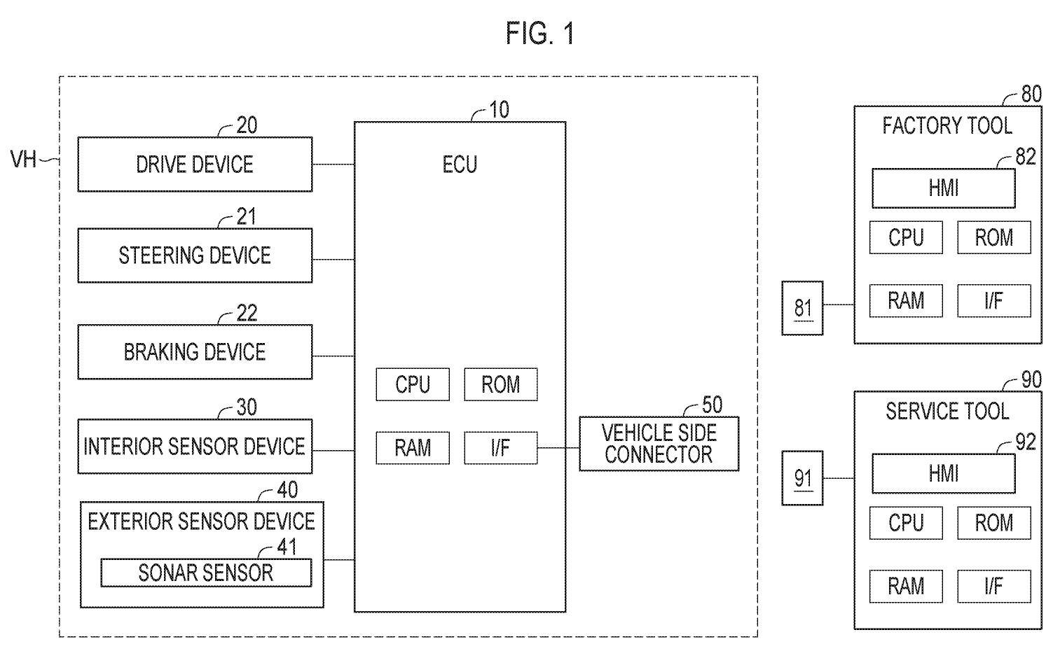

FIG. 1 is a schematic diagram showing a hardware configuration of a vehicle VH to which a control device according to the present embodiment is applied.

The vehicle vh includes an ecu 10. the ecu 10 includes a central processing unit (cpu), a read only memory (rom), a random access memory (ram), an interface if, and the like. The cpu is a processor that executes various programs stored in the rom (storage medium). the rom is a non-volatile memory, and stores data or the like needed for the cpu to execute various programs. The ram is a volatile memory, and provides a work area in which various programs are expanded when the various programs are executed by the cpu. The interface if is a communication device for communicating with an external device.

The ECU 10 is a device that serves as a center for performing various controls, such as driving assistance. The driving assistance is a concept including autonomous driving. The drive device 20, the steering device 21, the braking device 22, the interior sensor device 30, the exterior sensor device 40, a vehicle side connector 50, and the like are communicably connected to the ECU 10.

The drive device 20 generates a drive force transmitted to drive wheels of the vehicle VH. Examples of the drive device 20 include an electric motor and an engine. The steering device 21 applies a turning force to wheels of the vehicle VH. The braking device 22 applies a braking force to wheels of the vehicle VH.

The interior sensor device 30 is a sensor or the like that detects a state of the vehicle VH. As an example, the interior sensor device 30 includes a vehicle speed sensor, an accelerator sensor, a brake sensor, and a steering angle sensor. The interior sensor device 30 transmits the state of the vehicle VH detected by the sensors at a predetermined cycle to the ECU 10.

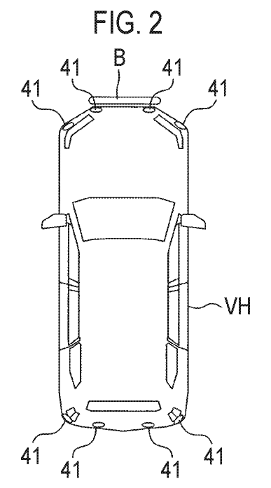

The exterior sensor device 40 is a sensor that recognizes object information regarding an object around the vehicle VH. As an example, the exterior sensor device 40 includes a sonar sensor 41. Here, examples of the object information include a stationary object, such as a wall, and a moving object, such as a surrounding vehicle or a pedestrian. The sonar sensor 41 acquires a distance between the vehicle VH and the object or the like by emitting an ultrasonic wave and receiving a reflected wave reflected by an object present in an emission range. The number of the sonar sensors 41 is not particularly limited. As an example, as shown in FIG. 2, two sonar sensors 41 are provided on a front surface of a front bumper of the vehicle VH at a predetermined interval in a vehicle width direction. In addition, eight sonar sensors 41 are provided: one each on right and left end portions of the front bumper, two on a front surface of the rear bumper at a predetermined interval in the vehicle width direction, and one each on right and left end portions of the rear bumper.

The exterior sensor device 40 repeatedly transmits the object information acquired by the sonar sensor 41 to the ECU 10 at a predetermined cycle. The exterior sensor device 40 is not limited to the sonar sensor 41, and may further include a millimeter wave radar, a lidar, a camera sensor, or the like.

The vehicle side connector 50 is connected to the interface IF of the ECU 10 via a communication cable (not shown). The vehicle side connector 50 is configured to be connectable to a first tool side connector 81 of the factory tool 80 and a second tool side connector 91 of the service tool 90. Here, the factory tool 80 is a dedicated terminal distributed to a site of a factory that manufactures the vehicle VH or the like. The factory tool 80 is used to write a setting value, such as the sensor information of the sonar sensor 41, in the storage unit (for example, the ROM) of the ECU 10, or to write various parameters of the vehicle VH or the like. The service tool 90 is a dedicated terminal distributed to a dealer, a repair shop, or the like where the vehicle VH is actually used. The service tool 90 is used to rewrite the setting value of the sensor information or various parameters stored in the storage unit of the ECU 10, or to update the program. The sensor information and various parameters are examples of the setting value related to the vehicle of the present disclosure.

The factory tool 80 and the service tool 90 include a CPU, a ROM, a RAM, an interface IF, and the like. In addition, the factory tool 80 and the service tool 90 further include a human machine interface (HMI) 82, 92. The HMI 82, 92 includes an input device and a display device. The input device and the display device may be a touch panel display. In addition, the input device may include a microphone that receives a voice input.

### First Embodiment

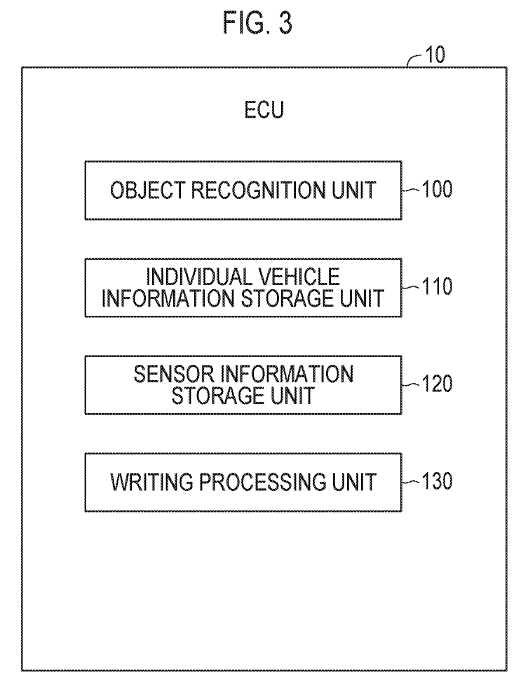

FIG. 3 is a schematic diagram showing a software configuration of the ECU 10 according to the first embodiment. As shown in FIG. 3, the ECU 10 includes an object recognition unit 100, an individual vehicle information storage unit 110, a sensor information storage unit 120, a writing processing unit 130, and the like as functional units. Each of the functional units 100 to 130 is realized by the CPU of the ECU 10 reading and executing a program stored in the ROM into the RAM. All or a part of the functional units 100 to 130 can be provided in another ECU different from the ECU 10, or in an information processing device of a facility (management center or the like) communicable with the vehicle VH.

The object recognition unit 100 recognizes a surrounding object, such as a stationary object or a moving object, present around the vehicle VH based on the detection result of the sonar sensor 41 and a setting value of the sensor information stored in the sensor information storage unit 120 described below. Specifically, the object recognition unit 100 recognizes a distance between the vehicle VH and the surrounding object present in the vicinity of the vehicle VH and a direction of the surrounding object with respect to the vehicle VH based on the detection result of the sonar sensor 41 and an initial setting value (hereinafter, referred to as "initial setting value") written in the sensor information storage unit 120 by using the factory tool 80. In addition, when the setting value (hereinafter, referred to as "changed setting value") written in the sensor information storage unit 120 by using the service tool 90 is stored, the object recognition unit 100 recognizes the distance between the vehicle VH and the surrounding object present in the vicinity of the vehicle VH and the direction of the surrounding object with respect to the vehicle VH based on the detection result of the sonar sensor 41 and the changed setting value. A recognition result (distance, direction, and the like) of the surrounding object recognized by the object recognition unit 100 is used for various controls. The various controls are warning control of emitting a warning sound from an in-vehicle speaker or the like when the surrounding object abnormally approaches the vehicle VH, automatic brake control for reducing a collision damage between the vehicle VH and the surrounding object, and the like.

The individual vehicle information storage unit 110 is an example of a storage unit of the present disclosure. The individual vehicle information storage unit 110 stores information as to whether the vehicle VH is a compatible vehicle that can attach a bull bar or a nudge bar (see reference numeral B in FIG. 2) or a non-compatible vehicle in which the installation of the bull bar or the nudge bar is not assumed. The writing of the individual vehicle information may be input by using the factory tool 80, for example, at the time of manufacturing the vehicle VH or at the time of factory shipment. As in the second embodiment described below, in a case where devices for means of rear visibility or detection (UNR158) are corresponded to by the sonar sensor 41, it is desirable that the vehicle VH is not considered as the compatible vehicle (that is, considered as the non-compatible vehicle) even though the bull bar or the nudge bar can be attached to the vehicle VH.

The sensor information storage unit 120 is an example of a storage unit of the present disclosure, and stores sensor information of the sonar sensor 41 installed in the bumper of the vehicle VH. Here, the sensor information includes a setting value such as a mounting position of the sonar sensor 41 in the bumper. The sensor information storage unit 120 stores an initial setting value written by using the factory tool 80 or a changed setting value written by using the service tool 90 based on a determination result of the writing processing unit 130 described below. In the present embodiment, the sensor information storage unit 120 stores the initial setting value and the changed setting value in a distinguishable manner.

The writing processing unit 130 is an example of a controller of the present disclosure, and executes a writing process of storing a setting value of the sensor information written by using the factory tool 80 or the service tool 90 in the sensor information storage unit 120. Specifically, the writing processing unit 130 first stores an initial setting value written by using the factory tool 80 in the sensor information storage unit 120 as the sensor information when the sonar sensor 41 is initialized at the time of manufacturing the vehicle VH.

The writing processing unit 130 rejects the storage of the setting value even when the writing of the setting value of the sensor information is performed by using the service tool 90 at the dealer, the repair shop, or the like, in a case where a determination is made based on the individual vehicle information stored in the individual vehicle information storage unit 110 that the vehicle VH is a non-compatible vehicle that does not assume the installation of the bull bar or the nudge bar (in a case where a determination is made that the vehicle VH satisfies a predetermined condition of the present disclosure). That is, the initial setting value stored in advance is held in the sensor information storage unit 120. As a result, it is possible to prevent the setting value of the sensor information from being unnecessarily rewritten. It is possible to correspond to regulations that regulate rewriting of software, such as a software update management system (SUMS).

The writing processing unit 130 stores the setting value in the sensor information storage unit 120 as the changed setting value when the writing of the setting value of the sensor information is performed by using the service tool 90 at the dealer, the repair shop, or the like, in a case where a determination is made based on the individual vehicle information stored in the individual vehicle information storage unit 110 that the vehicle VH is a compatible vehicle that can attach the bull bar or the nudge bar (in a case where a determination is made that the vehicle VH does not satisfy a predetermined condition of the present disclosure). As a result, it is possible to store the setting value of the sensor information according to the bumper or the bull bar or the nudge bar attached in the market, and to effectively prevent the erroneous operation of the various controls based on the detection result of the sonar sensor 41.

The sonar sensor 41 may be replaced at a dealer or a repair shop due to a failure, a replacement life, or the like. When the sonar sensor 41 is replaced, the initialization of the sonar sensor 41 is performed at a dealer or a repair shop. The writing processing unit 130 holds the changed setting value in the sensor information storage unit 120 when the initialization of the sonar sensor 41 is performed at the dealer or the repair shop and the changed setting value written in the sensor information storage unit 120 by using the service tool 90 is stored. In addition, when the initialization of the sonar sensor 41 is performed at the dealer or the repair shop and the initial setting value written in the sensor information storage unit 120 by using the factory tool 80 is stored, the writing processing unit 130 holds the initial setting value in the sensor information storage unit 120.

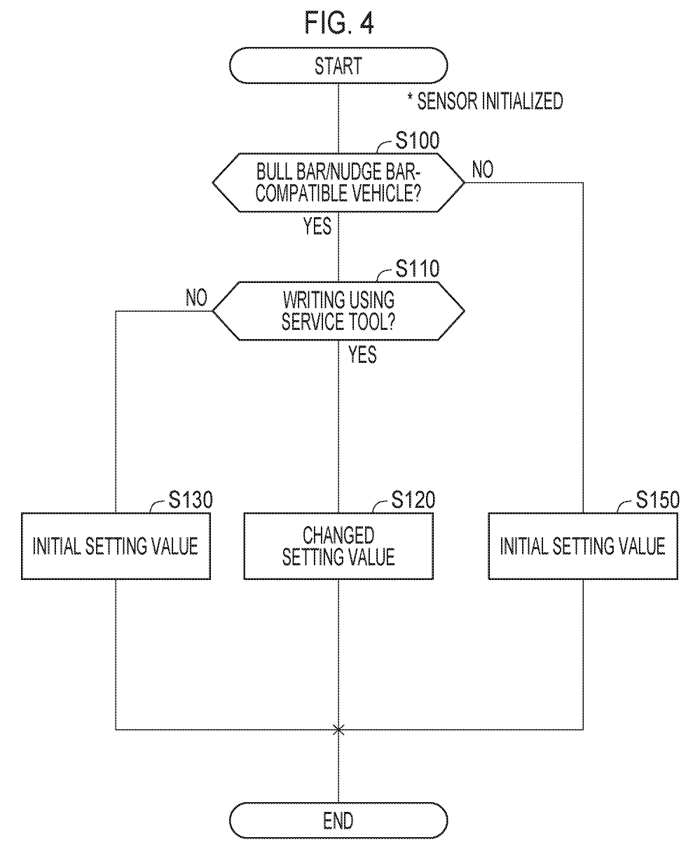

Next, a flow of a writing process of the sensor information executed by the CPU 11 of the ECU 10 according to the first embodiment will be described with reference to FIG. 4. The present routine is started, for example, when the sonar sensor 41 is initialized.

In S100, the ECU 10 determines whether the vehicle VH is a compatible vehicle that can attach the bull bar or the nudge bar based on the individual vehicle information. When the vehicle VH is a compatible vehicle that can attach the bull bar or the nudge bar (Yes), the ECU 10 proceeds to the process of S110. On the other hand, in a case where the vehicle VH is not a compatible vehicle that can attach the bull bar or the nudge bar (No), that is, in a case where the vehicle VH is a non-compatible vehicle that does not assume the installation of the bull bar or the nudge bar, the ECU 10 proceeds to the process of S150.

In S150, the ECU 10 stores the initial setting value written by using the factory tool 80 as the sensor information of the sonar sensor 41, and ends the present routine. That is, it is possible to effectively prevent the setting value of the sensor information from being unnecessarily rewritten from the initial setting value.

When proceeding from the process of S100 to S110, the ECU 10 determines whether the writing of the setting value of the sensor information using the service tool 90 is performed at a dealer, a repair shop, or the like. When the writing using the service tool 90 is not performed (No), the ECU 10 proceeds to the process of S130, holds the initial setting value written as the sensor information of the sonar sensor 41 by using the factory tool 80, and ends the present routine. On the other hand, in a case where the writing using the service tool 90 is performed (Yes), the ECU 10 proceeds to the process of S120, stores the setting value written by using the service tool 90 as the changed setting value, and ends the present routine. That is, it is possible to correspond to the bull bar or the nudge bar attached in the market, and to effectively prevent the erroneous operation of the various controls.

### Second Embodiment

The control device of the vehicle and the program according to the second embodiment are characterized in that the individual vehicle information storage unit 110 stores information as to whether the vehicle VH is a vehicle corresponding to devices for means of rear visibility or detection (UNR158) by the sonar sensor 41 as the individual vehicle information. Since the configuration of the individual vehicle information storage unit 110 and the writing processing unit 130 is the same as that of the first embodiment, the description thereof will be omitted.

In the second embodiment, the writing processing unit 130 rejects the storage of the setting value even when the writing of the setting value of the sensor information is performed by using the service tool 90 at the dealer, the repair shop, or the like, in a case where a determination is made based on the individual vehicle information stored in the individual vehicle information storage unit 110 that the vehicle VH is a compatible vehicle that can attach the devices for means of rear visibility or detection (UNR158) by the sonar sensor 41 (in a case where a determination is made that the vehicle VH satisfies a predetermined condition of the present disclosure). That is, the initial setting value stored in advance is held in the sensor information storage unit 120. As a result, it is possible to prevent the setting value of the sensor information from being unnecessarily rewritten, and to appropriately correspond to the SU regulation, the UNR158 regulation, or the like.

On the other hand, in a case where a determination is made that the vehicle VH is a non-compatible vehicle that does not correspond to the devices for means of rear visibility or detection (UNR158) by the sonar sensor 41 (in a case where a determination is made based on the individual vehicle information stored in the individual vehicle information storage unit 110 that the vehicle VH does not satisfy a predetermined condition of the present disclosure), the writing processing unit 130 stores the setting value as the changed setting value in the sensor information storage unit 120 when the writing of the setting value of the sensor information is performed by using the service tool 90 at the dealer, the repair shop, or the like. As a result, it is possible to store the setting value of the sensor information according to the bumper or the bull bar or the nudge bar attached in the market, and to effectively prevent the erroneous operation of the various controls based on the detection result of the sonar sensor 41.

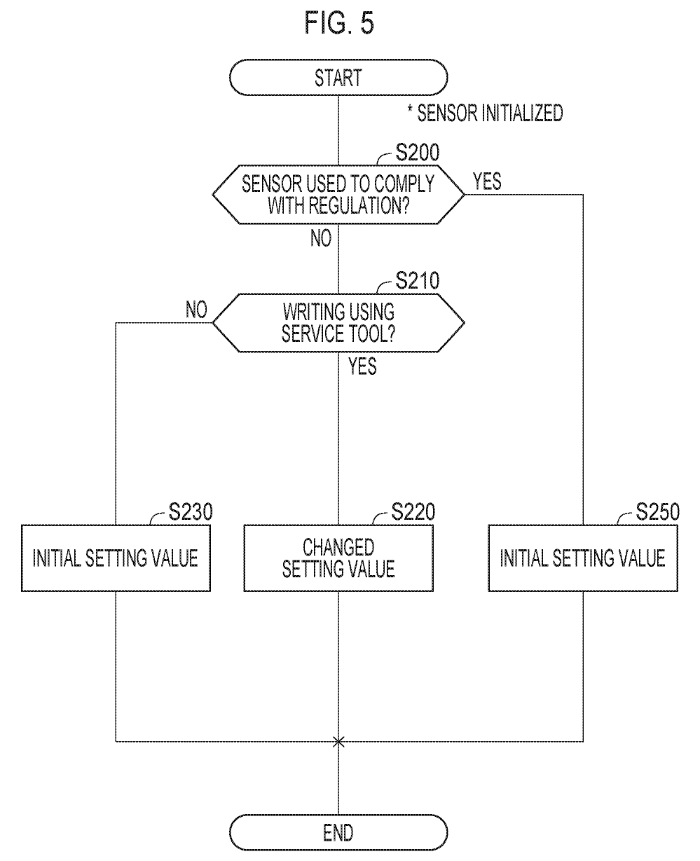

Next, a flow of a writing process of the sensor information executed by the CPU 11 of the ECU 10 according to the second embodiment will be described with reference to FIG. 5. The present routine is started, for example, when the sonar sensor 41 is initialized.

In S200, the ECU 10 determines whether the vehicle VH is a compatible vehicle that corresponds to the regulation (UNR158) by the sonar sensor 41 based on the individual vehicle information. When the vehicle VH is not a compatible vehicle that corresponds to the regulation (UNR158) by the sonar sensor 41 (No), that is, when the vehicle VH is a non-compatible vehicle that does not correspond to the regulation (UNR158) by the sonar sensor 41, the ECU 10 proceeds to the process of S210. On the other hand, in a case where the vehicle VH is a compatible vehicle that corresponds to the regulation (UNR158) by the sonar sensor 41 (Yes), the ECU 10 proceeds to the process of S250.

In S250, the ECU 10 stores the initial setting value written by using the factory tool 80 as the sensor information of the sonar sensor 41, and ends the present routine. That is, it is possible to effectively prevent the setting value of the sensor information from being unnecessarily rewritten from the initial setting value.

When proceeding from S200 to S210, the ECU 10 determines whether the writing of the setting value of the sensor information using the service tool 90 is performed at a dealer, a repair shop, or the like. When the writing using the service tool 90 is not performed (No), the ECU 10 proceeds to the process of S230, holds the initial setting value written as the sensor information of the sonar sensor 41 by using the factory tool 80, and ends the present routine. On the other hand, in a case where the writing using the service tool 90 is performed (Yes), the ECU 10 proceeds to the process of S220, stores the setting value written by using the service tool 90 as the changed setting value, and ends the present routine. That is, it is possible to correspond to the bull bar or the nudge bar attached in the market, and to effectively prevent the erroneous operation of the various controls.

### Third Embodiment

The control device of the vehicle and the program according to the third embodiment are characterized in that the individual vehicle information storage unit 110 stores information as to whether a destination of the vehicle VH corresponds to a jurisdiction that is subject to regulations for regulating software updates, as the individual vehicle information. Since the configuration of the individual vehicle information storage unit 110 and the writing processing unit 130 is the same as that of the first embodiment and the second embodiment, the description thereof will be omitted.

In the third embodiment, the writing processing unit 130 rejects the storage of the setting value even when the writing of the setting value of the sensor information is performed by using the service tool 90 at the dealer, the repair shop, or the like, in a case where a determination is made based on the individual vehicle information stored in the individual vehicle information storage unit 110 that the destination of the vehicle VH corresponds to a jurisdiction (for example, an SU regulation) in which the software updates are regulated (in a case where a determination is made that the vehicle VH satisfies a predetermined condition of the present disclosure). That is, the initial setting value stored in advance is held in the sensor information storage unit 120. As a result, it is possible to prevent the setting value of the sensor information from being unnecessarily rewritten, and to appropriately correspond to the regulation, such as the SU regulation.

On the other hand, in a case where a determination is made based on the individual vehicle information stored in the individual vehicle information storage unit 110 that the destination of the vehicle VH does not correspond to a jurisdiction that is subject to the regulations for regulating the software updates (in a case where a determination is made that the vehicle VH does not satisfy a predetermined condition of the present disclosure), the writing processing unit 130 stores the setting value as the changed setting value in the sensor information storage unit 120 when the writing of the setting value of the sensor information is performed by using the service tool 90 at the dealer, the repair shop, or the like. As a result, it is possible to store the setting value of the sensor information according to the bumper or the bull bar or the nudge bar attached in the market, and to effectively prevent the erroneous operation of the various controls based on the detection result of the sonar sensor 41.

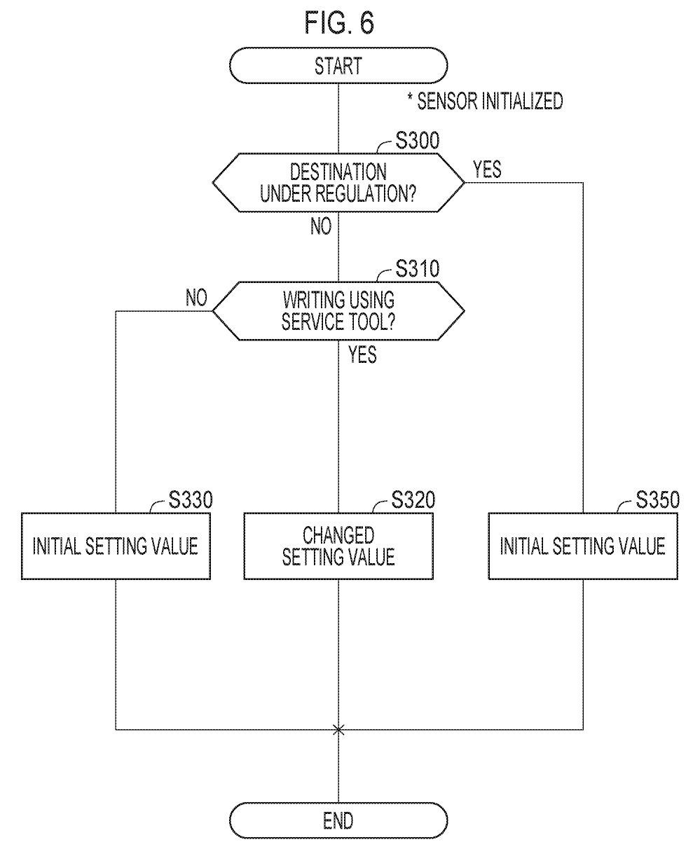

Next, a flow of a writing process of the sensor information executed by the CPU 11 of the ECU 10 according to the third embodiment will be described with reference to FIG. 6. The present routine is started, for example, when the sonar sensor 41 is initialized.

In S300, the ECU 10 determines whether a destination of the vehicle VH corresponds to a jurisdiction (SU regulation) in which software updates are regulated based on the individual vehicle information. When the destination of the vehicle VH does not correspond to a jurisdiction (SU regulation) (No), the ECU 10 proceeds to the process of S310. On the other hand, in a case where the destination of the vehicle VH corresponds to a jurisdiction (SU regulation) (Yes), the ECU 10 proceeds to the process of S350.

In S350, the ECU 10 stores the initial setting value written by using the factory tool 80 as the sensor information of the sonar sensor 41, and ends the present routine. That is, it is possible to effectively prevent the setting value of the sensor information from being unnecessarily rewritten from the initial setting value.

When proceeding from the process of S300 to S310, the ECU 10 determines whether the writing of the setting value of the sensor information using the service tool 90 is performed at a dealer, a repair shop, or the like. When the writing using the service tool 90 is not performed (No), the ECU 10 proceeds to the process of S330, holds the initial setting value written as the sensor information of the sonar sensor 41 by using the factory tool 80, and ends the present routine. On the other hand, in a case where the writing using the service tool 90 is performed (Yes), the ECU 10 proceeds to the process of S320, stores the setting value written by using the service tool 90 as the changed setting value, and ends the present routine. That is, it is possible to correspond to the bull bar or the nudge bar attached in the market, and to effectively prevent the erroneous operation of the various controls.

Although the control device of the vehicle and the program according to the present embodiment have been described above, the present disclosure is not limited to the present embodiment, and can be variously modified without departing from an object of the present disclosure.

For example, in the above-described embodiment, the sonar sensor 41 has been described as an example of the object detection sensor, but the present disclosure can be widely applied to a writing process of sensor information of other object detection sensors, such as a radar sensor or a camera sensor. In addition, in the above-described embodiment, the bull bar or the nudge bar is exemplified, but the present disclosure can be widely applied to other exterior parts that are attached to a front bumper or a rear bumper and may interfere with a detection range of the sensor.

What is claimed is:

1. A control device of a vehicle, the control device comprising:
a storage unit configured to store individual vehicle information of the vehicle and a setting value relating to the vehicle; and
a controller configured to
reject, in a case where a determination is made based on the individual vehicle information that the vehicle satisfies a predetermined condition relating to a regulation, storing a new setting value as the setting value in the storage unit even when the new setting value is written by a service tool, and
store, in a case where a determination is made based on the individual vehicle information that the vehicle does not satisfy the predetermined condition, the new setting value in the storage unit when the new setting value is written by the service tool.

2. The control device according to claim 1, wherein:
the storage unit is configured to store, as the individual vehicle information, any one of first information indicating whether the vehicle is a compatible vehicle to which a bull bar or a nudge bar is attachable, second information indicating whether a sensor included in the vehicle is a sensor installed for regulatory compliance, or third information indicating whether a destination of the vehicle is in a jurisdiction that is subject to a regulation relating to a software update; and
the controller is configured to determine that the predetermined condition is satisfied in a case where the first information indicates that the vehicle is not the compatible vehicle, in a case where the second information indicates that the sensor is the sensor installed for regulatory compliance, or in a case where the third information indicates that the destination is in the jurisdiction that is subject to the regulation.

3. The control device according to claim 1, wherein:
the storage unit is configured to store, as the setting value relating to the vehicle, a value written by a factory tool at a time of manufacturing the vehicle as an initial setting value, in advance; and
the controller is configured to keep, in a case where a determination is made that the predetermined condition is satisfied and also in a case where a determination is made that the predetermined condition is not satisfied, the initial setting value stored in the storage unit in a case where no writing is performed by the service tool.

4. The control device according to claim 1, wherein:
the vehicle includes an object detection sensor provided in a bumper of the vehicle, the object detection sensor being configured to detect an object present near the vehicle; and
the storage unit is configured to store, as the setting value relating to the vehicle, information on an installation position of the object detection sensor in the bumper.

5. A non-transitory storage medium storing a program that causes a computer of a control device of a vehicle to execute a process comprising:
storing individual vehicle information of the vehicle and a setting value relating to the vehicle; and
rejecting, in a case where a determination is made based on the individual vehicle information that the vehicle satisfies a predetermined condition relating to a regulation, storing a new setting value as the setting value even when the new setting value is written by a service tool, and storing, in a case where a determination is made based on the individual vehicle information that the vehicle does not satisfy the predetermined condition, the new setting value when the new setting value is written by the service tool.
